(19) United States
(12) Patent Application Publication
(10) Pub. No.: US 2023/0140418 A1
(43) Pub. Date: May 4, 2023

(54) PROCESS FOR MANUFACTURING AN ELECTRICALLY CONDUCTING DEVICE FROM LIGNOCELLULOSIC MATERIAL

(71) Applicant: SAS WOODOO, Paris (FR)

(72) Inventors: Sébastien PATOUR, Paris (FR); Timothée BOITOUZET, Paris (FR)

(21) Appl. No.: 18/148,227

(22) Filed: Dec. 29, 2022

Related U.S. Application Data
(63) Continuation of application No. PCT/FR2021/051236, filed on Jul. 6, 2021.

(30) Foreign Application Priority Data
Jul. 8, 2020 (FR) 2007230

(51) Int. Cl. C08J 7/044; C08J 7/04

(52) U.S. Cl. CPC C08J 7/044; C08J 7/0427; C08J 2397/02

(57) ABSTRACT

A process for manufacturing an electrically conducting device from lignocellulosic material comprises the following steps:
impregnating (S10) the lignocellulosic material with at least one filling compound so as to produce a composite substrate; and
depositing (S12) at least one conducting layer on at least one surface of the composite substrate so as to produce an electrically conducting device.
   Use of an electrically conducting device so produced for example particularly as a touch interface.

### CROSS-REFERENCE TO RELATED APPLICATIONS

This application is a continuation of International Patent Application No. PCT/FR2021/051236, filed Jul. 6, 2021, which claims priority to French Patent Application No. 2007230, filed Jul. 8, 2020, which applications are incorporated herein by reference in their entirety for all purposes.

### BACKGROUND

The present invention concerns a process for manufacturing an electrically conducting device from lignocellulosic material.

It also concerns an electrically conducting device of lignocellulosic material obtained by such a process.

The field of the Internet of Things (IoT), of home automation and of smart surfaces, and the proliferation of display and control screens increase the need today for interactivity through electronic functions that are directly integrated into objects.

Payment cards, whether contactless or with contact, access control badges, and cards with an authenticity certificate are also used increasingly in everyday life.

In particular, touch interfaces for controlling the operation of a device are used today in very diverse fields: transport (automotive, nautical, aeronautical), construction, packaging, access security and for instance furnishings.

### SUMMARY

Currently, touch interfaces are often produced from a glass or silica substrate on which is deposited and bonded a plastic film, generally a thin layer of PET (PolyEthyleneTerephthalate), bearing a printed circuit for example of ITO (Indium Tin Oxide). Touch interfaces with capacitive detection are thus provided.

These touch interfaces are often thick, heavy and fragile, and dimensionally limited to flat applications in two dimensions.

Their manufacture moreover requires a high temperature deposition of ITO, in a controlled environment, generating high energy expenditure, which increases the cost of their manufacturing process and makes it complex. These manufacturing processes also have a high carbon footprint.

Alternatives to glass substrates have been proposed, such as plastic substrates enabling the development of flexible screens. However, the ITO deposition temperature is limited on such plastic substrates, which reduces the electrical and optical performance of such structures.

From the document WO 2019/055680 there is also known a touch interface developed using a non-polymer substrate, such as paper, a textile, ceramic, wood or a foam. Electrically conducting tracks are deposited directly on the substrate, by printing with a conducting ink or via a water transfer printing technique, which is well suited to substrates in three dimensions.

However, the quality of the deposition of an electrically conducting coating is strongly dependent on the nature of the substrate and on the surface which receives it. The electrical operation of the conducting circuit so produced is also influenced by the nature of the substrate and its dielectric qualities.

The present invention is directed to providing an alternative to the existing solutions, while simplifying the manufacture of an electrically conducting device whatever the final shape, and at the same time ensuring good quality electrical conduction of the device so obtained.

According to a first aspect, the present invention concerns a process for manufacturing an electrically conducting device from lignocellulosic material.

According to the invention, the manufacturing process comprises the following steps:
impregnating the lignocellulosic material with at least one filling compound so as to produce a composite substrate; and
depositing at least one conducting layer on at least one surface of the composite substrate so as to produce the electrically conducting device.

Such a process thus makes it possible to deposit an electrically conducting coating directly on a lignocellulosic substrate, in contact with the surface of the composite substrate, in order to add an electrical and/or electronic function to the device so manufactured. The use of an intermediate plastic film, bonded onto the substrate, is thus unnecessary. The functionalization of the lignocellulosic substrate without having to bond, with an adhesive, a plastic film incorporating printed electronics, makes it possible, for the same functionality, to reduce the number of parts to employ, to simplify the assembly and to reduce the manufacturing costs.

Furthermore, such a process makes it possible to use a lignocellulosic material, derived from biomass with a favorable carbon impact in order to produce parts and surfaces that are smart, interactive and three-dimensional.

Impregnating the lignocellulosic substrate with a filling compound enables the lignocellulosic substrate to be dimensionally stabilized, improving the final structure of the electrically conducting device.

Furthermore, the impregnation makes it possible to homogenize the surface state of the composite substrate that is to receive the deposit of at least one conducting layer. The surface of the composite substrate may be controlled and has fewer asperities or hollows thanks to the impregnation with a filling compound.

The substrate of lignocellulosic material, such as untreated wood, thus has lower roughness after impregnation, improving the quality of the conducting layer deposit, and thus the conductive properties thereof on use of the electrically conducting device so obtained. The low roughness of the composite substrate makes it possible to improve the adhesion of the conducting layer and its conductivity.

It is thus possible to deposit a network of electronic components or to transform the impregnated lignocellulosic substrate into a semiconducting element. The electrically conducting device may in particular form a control interface in two dimensions or in three dimensions.

According to an advantageous feature of the invention, the composite substrate comprises a fraction of a filling compound comprised between 30% and 80% by weight relative to the total weight of said substrate.

The filling compound makes it possible to improve the dielectric qualities of the lignocellulosic substrate. By replacing the pores and air pockets to the core in the lignocellulosic substrate, the filling compound increases the electrical insulation properties of the composite substrate.

In practice, the filling compound is an impregnation polymer, for example a thermoplastic polymer, of acrylic type.

A polymer is well suited for modifying and controlling the dielectric properties of the composite substrate so produced.

Furthermore, a thermoplastic polymer is well suited for the later shaping of the composite substrate, in particular by shaping while hot, such as by thermoforming or thermocompression.

According to an advantageous feature of the invention, the lignocellulosic material is wood comprising lignin and a network of cellulose and hemicellulose, the wood being at least partially delignified.

The at least partial removal of the lignin enables the optical properties of the composite substrate to be optimized. As lignin is degraded under the effect of ultraviolet radiation, provided at least some of the lignin is removed, the composite substrate is more resistant to natural degradation and ultraviolet ageing.

The removal of lignin coupled with impregnation with the filling compound enables the composite substrate to be rendered less sensitive to variations in humidity and to temperature changes.

These properties are important for the optimum functioning of the electrically conducting device, and in particular for the stability of the dielectric properties of the composite substrate. The electrically conducting device so obtained may thus be used in different environments, both inside and outside, while ensuring proper electrical operation.

In one practical embodiment, the composite substrate comprises at least one planar face, a conducting track being deposited on the surface of said at least one planar face.

The deposition of a conducting layer may be carried out by screen-printing of a conducting track on the surface of the composite substrate, screen-printing being well suited to mass production. Screen-printing is well suited to the deposition of a conducting ink in particular. A technique of depositing a conducting ink by ink jet may also be implemented for small series productions.

Thanks to the improved surface state through impregnation with the lignocellulosic substrate, a technique of depositing by screen-printing may be satisfactorily implemented, with good adhesion of the conducting layer so deposited and good electrical continuity. Deposition by screen-printing or by conducting ink jet enables a step of depositing a conducting layer to be implemented at ambient temperature. It enables an electronic circuit printed on the composite substrate to be obtained.

Depositing the conducting layer at ambient temperature makes it possible to avoid the use of high temperature which is required for ITO deposition.

In an improved embodiment, the manufacturing process further comprises a step of baking the conducting track, optionally followed by a step of shaping the composite substrate so as to produce an electrically conducting device in three dimensions.

The baking of the conducting track eliminates the solvents and the volatile compounds of the conducting track deposited on the composite substrate.

It is thus possible to employ a conducting ink that requires baking after disposition. It may be used in applications in which the composite substrate has to be shaped to obtain an electrically conducting device in three dimensions. The baking of the conducting ink furthermore improves its electrical conductivity properties.

The shaping step, when it employs shaping while hot of the composite substrate, enables the electrical conductivity properties of the conducting ink to be improved through a second baking of the conducting ink.

In one embodiment, the filling compound is a resin having a filler of metal particles, the manufacturing process further comprising a step of activating the metal particles by ultraviolet or laser beam before the depositing step.

It is thus possible to engrave tracks by locally activating the resin having a filler of metal particles, which then enables the deposition of a conducting layer by immersing the composite substrate in one or more baths of metals in suspension.

Metalization of the tracks locally activated on the composite substrate is thus obtained, the metal in suspension becoming adhered to the activated metal particles.

Such a manufacturing process is well suited to producing a electrically conducting device in three dimensions.

In practice, the manufacturing process may comprise a step of shaping the composite substrate after the impregnating step and before the depositing step.

The conducting layer is thus directly applied to one or more surfaces in three dimensions of the composite substrate, after thermoforming or thermocompression for example.

In one practical embodiment, the composite substrate is a plate comprising two opposite faces, the manufacturing process comprising a step of depositing at least one conducting layer on at least one surface of one of the two faces of the plate.

The process thus makes it possible to functionalize a plate by providing a conducting element on one of the two faces, such as an electrode or a mesh of conducting wires for example, thereby transforming the plate into a touch control interface, based on the detection of a touch on the opposite face. It is thus possible to obtain a touch control interface, having capacitive or resistive detection technology.

In practice, the thickness of the plate is less than 10 mm.

By limiting the thickness of the composite substrate, it is possible to use the electrically conducting device as a coating or as a control interface disposed on an electronic object.

Advantageously, the composite substrate is translucent or transparent, the light transmission coefficient of the translucent substrate being at least equal to 3%.

The translucence of the composite substrate enables it to be used in association with a light-producing device, such as a display screen or an indicator light of LED (Light Emitting Diode) type. The transmission of light rays and thus of information is made possible.

Preferably, the conducting layer comprises a transparent conducting ink.

The use of a transparent conducting ink, in association with translucence or transparency of the composite substrate, enables the composite substrate to be used as an interface above a display screen for example.

In practice, the refractive index of the filling compound is comprised between 1.35 and 1.70.

The refractive index of the filling compound is thus close to that of the cellulose of the lignocellulosic material.

As a matter of fact, in order to obtain a composite substrate that is at least translucent, it is important for the refractive index of the filling compound to be close to that of the lignocellulosic substrate after at least partial delignification.

Thus, once the filling compound has polymerized, it has substantially the same optical density as that of the cellulose present in the substrate.

As the refractive index of cellulose is close to 1.47, the choice of a filling compound having a refractive index comprised in the range from 1.35 to 1.70, makes it possible to have refractive indexes close to each other. Light can thus pass through the composite substrate substantially without being deviated.

According to a second aspect, the present invention concerns an electrically conducting device of lignocellulosic material obtained by the manufacturing process according to the invention.

This electrically conducting device has features and advantages that are similar to those described above in relation to the process.

In practice, the device electrically constitutes a interface for control of an electronic object, a payment card, an access control badge, a sensor, a transistor, a resistor, an energy generating device or an electrical conductor.

Such an electrically conducting device for example forms an automotive, nautical or aeronautical vehicle part, or a member or accessory in the building, packaging or furnishings fields.

Still other particularities and advantages of the invention will appear in the following description.

### BRIEF DESCRIPTION OF DRAWINGS

In the accompanying drawings, given by way of non-limiting example:

FIG. 1 is a block diagram illustrating an example embodiment of the process for manufacturing an electrically conducting device according to the invention;

FIG. 2a is a front view of an antenna produced according to an embodiment of the process for manufacturing an electrically conducting device of the invention.

FIG. 2b is an exploded perspective view of the antenna of FIG. 2a;

FIG. 3a illustrates a first step for producing a touch interface from lignocellulosic material according to an example embodiment of the process for manufacturing an electrically conducting device of the invention; and

FIG. 3b illustrates a second step for producing a touch interface from lignocellulosic material of FIG. 3a.

### DETAILED DESCRIPTION

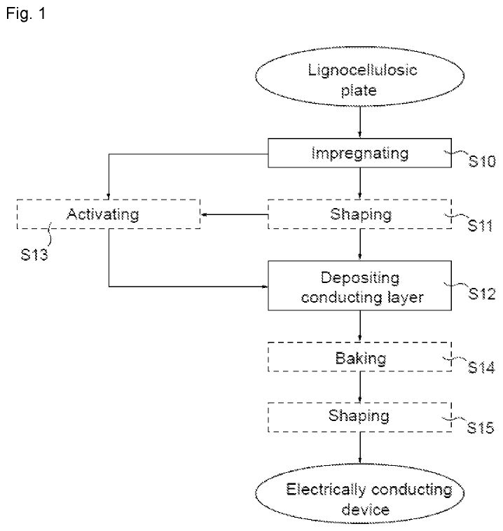

First of all a description will be made with reference to FIG. 1 of an example of a process for manufacturing an electrically conducting device from lignocellulosic material.

The lignocellulosic material is for example wood comprising lignin and a network of cellulose and hemicellulose.

By way of example, different types of wood may be used, such as oak, walnut, poplar, maple, ash or softwood.

The manufacturing process may employ a lignocellulosic material that is untreated, or that is partially or totally delignified.

By way of non-limiting example, the fraction of lignin removed from the untreated lignocellulosic material may be comprised between 40% and 90% by weight of the lignin present initially in the untreated lignocellulosic material.

The at least partial delignification of the lignocellulosic material makes it possible to obtain a part made of wood that is at least translucent, and possibly transparent.

Furthermore, as lignin is degraded by ultraviolet on use of a part made from lignocellulosic material, the at least partial delignification of the lignocellulosic material makes it possible to obtain a part that is more resistant to degradation under the effect of light or ultraviolet.

In the example embodiment described below, the manufacturing process is performed on the basis of a plate of lignocellulosic material. Of course, the manufacturing process may be formed on any other type of shape, in two or three dimensions.

The manufacturing process first of all comprises a step S10 of impregnating the lignocellulosic material by at least one filling compound so as to produce a composite substrate.

The impregnating step S10 employs a filling compound configured to impregnate the lignocellulosic material to the core, within its thickness.

The filling compound is thus configured to fill the interstices and voids naturally present in the untreated lignocellulosic material and/or created by the at least partial delignification of the lignocellulosic material.

The filling compound may be an impregnation polymer, an elastomer, a silica derivative or any other type of impregnation compound.

By way of example, the impregnation polymer may be a thermoplastic polymer of acrylic type.

Alternatively, the impregnation polymer may be a thermosetting resin.

The filling compound may be petro-sourced or bio-sourced.

A process for impregnating a lignocellulosic material is known to the person skilled in the art and is described in particular in the documents WO 2017/098149 and WO 2019/155159.

The impregnation process makes it possible to obtain impregnation to the core by the filling compound within the structure of the lignocellulosic material, in order to mechanically reinforce and sheathe the cellulose fibers of the wood.

The impregnating step S10 comprises a step of filling with a filling compound of the plate made of lignocellulosic material and a finishing step by polymerization and/or cross-linking of the filling compound. Multiple examples of the process of delignification and impregnation are described in detail in document WO 2017/098149, of which the content is incorporated by reference in the present description.

In particular, extraction of the lignin can be implemented by soaking and washing, which may possibly be paired in a single step, of the plate of lignocellulosic material in a solution enabling at least partial dissolution of the lignin.

Document WO 2019/155159 gives multiple examples of filling compounds, and of the proportions employed according to the nature of the wood used.

In particular, the filling compound may be a resin doped by conducting particles in order to modify and control the conductivity of the composite substrate thus produced.

Thus, by modifying the percentage of conducting particles in the filling compound, it is possible to control the dielectric qualities of a composite substrate obtained from a lignocellulosic material. In particular, contrary to an untreated lignocellulosic material, the composite substrate so obtained has a stable value of electrical conductivity, well suited to its use both indoors and outdoors.

When the filling compound is a polymer, the finishing step is operative to completely cross-link or polymerize the filling compound and thus ensure good physico-chemical stability of the composite substrate for its later use.

In general terms, the fraction of the filling compound in the composite substrate so obtained is comprised between 30% and 80% by weight relative to the total weight of the composite substrate.

The composite substrate so obtained may then optionally be shaped at a step of initial shaping S11, for example by shaping while hot.

The initial step of shaping S11 may be carried out by different techniques of shaping while hot, for example in particular by vacuum thermoforming or thermocompression.

Without being limitative, the shaping while hot may implement industrial processes used to produce composite parts, after Resin Transfer Molding (RTM) or High Pressure Resin Transfer Molding (HP-RTM).

The processes of shaping while hot may employ hot molding (RIM or Reaction Injection Molding), compression molding, or for instance a technique of sheet molding (employing SMC or Sheet Molding Compound).

According to its principle, thermoforming implements a step of heating the composite substrate obtained further to the impregnating step S10, then a step of heating the thermocompression mold.

The temperatures employed for heating the composite substrate and the mold depend on the vitreous transition temperature of the impregnation polymer.

Thus, the temperatures of heating the composite substrate and the thermoforming mold must be sufficient to fluidify the impregnation polymer, and enable the shaping of the composite substrate, while maintaining viscosity for this impregnation polymer in order to maintain the structure and support of the composite substrate.

Thus, when the composite substrate resulting from the impregnating step S10 is a plate, the step of initial shaping S11 makes it possible for example to curve that plate in one or more spatial directions so as to obtain a part of cylindrical, frusto-conical, or hemispherical shape, or any type of shape with dual curvature or warped surface.

Further to the impregnating step S10 or the initial shaping step S11, the manufacturing process comprises a step S12 of depositing at least one conducting layer on at least one surface of the composite substrate so as to produce an electrically conducting device.

The depositing step S12 is carried out after cooling of the composite substrate further to the impregnating step S10 or optionally after cooling further to the initial shaping step S11.

The depositing step S12 may employ different techniques for depositing a conducting layer on a substrate.

By way of non-limiting example, the depositing step S12 may be carried out using a screen-printing technique. Screen-printing is well suited to depositing a conducting track on the surface of a planar face of the composite substrate. The conducting track may be produced for example by means of a conducting ink.

Conventionally, stencils or screens are used and interposed between a conducting ink and the composite substrate.

Once the screen has been laid on the composite substrate, a liquid ink is deposited on the screen and spread over the surface using a squeegee.

The use of a screen or stencil makes it possible to obtain a great variety of conducting patterns, traces or tracks on the composite substrate.

A layer of conducting ink so deposited by screen-printing is in particular well-suited to high production volumes.

Of course, several layers of conducting ink may be deposited on the surface of the composite substrate, by interleaving between the conducting layers an insulating layer such as an insulating plastic film or a layer of electrically insulating ink.

Alternatively, a technique of depositing by conducting ink jet may be employed, in particular for manufacture in a small series.

If the composite substrate is of three-dimensional shape, and in particular if the conducting layer is not deposited on a flat surface, different processes of graphical printing onto a non-planar surface may be employed at depositing step S12.

In particular, water transfer printing may be used. A hydrographic film is printed with a hydrographic image before being deposited on the surface of water in a tank. As the hydrographic film is soluble in water, it dissolves thanks to the application of an activator solution to the water.

The composite substrate being dipped into the water of the tank, the surface tension of the water makes it possible to deposit the image from the hydrographic film onto one or more faces of the composite substrate.

According to another embodiment, the filling compound employed in the impregnating step S10 may be a resin having a filler of metal particles.

The manufacturing process then comprises an step S13 of activating the metal particles, for example by ultraviolet or laser beam, before the depositing step S12.

The ultraviolet or laser beam thus makes it possible to engrave tracks or different traces on the composite substrate impregnated with a resin having a filler of metal particles or an organometallic additive.

The material is thus activated locally, the ultraviolet or laser beam pulling away metal elements present in the resin having the filler.

In the depositing step S12 the composite substrate is then dipped into a bath and a deposit of a metallized conducting layer is obtained by electrolysis on the areas thus activated.

This depositing technique is used conventionally in molded interconnect devices, to produce plastic parts with in-built electronic functions.

It is particularly well suited to the implementation of the manufacturing process on a composite substrate of lignocellulosic material in three dimensions.

These various techniques of depositing a conducting layer are well known in the prior art and do not require to be described in more detail here.

Moreover, the above examples are not limiting and other techniques such as pressure transfer techniques, under the action of heat or wetting the composite substrate could also be implemented.

A photolithography process could also be implemented in depositing step S12, enabling an image to be transferred to the composite substrate, whatever its shape in two or three dimensions.

The manufacturing process next optionally comprises a step S14 of baking the conducting layer so deposited.

The baking step S14 makes it possible to eliminate the solvents and the volatile compounds of a conducting ink, and thereby improve the electrical conductivity of the deposited conducting ink.

The temperatures implemented at the baking step S14 are typically less than 180° C. in order to avoid any risk of burning the composite substrate of lignocellulosic material.

According to the type of inks or the conducting tracks produced, the temperatures are typically comprised between 100° C. and 150° C.

By way of non-limiting example, the baking step S14 may be implemented at a temperature of 130° C.

At the baking step S14, the composite substrate on which is deposited the conducting layer is placed in an oven at a controlled temperature for a predetermined time.

Alternatively, the baking step S14 may use the combined implementation of pressure and heat. Thus, two heating plates may be pressed against the surfaces of the composite substrate. Alternatively, a rolling machine may be used to apply a pressing force on the composite substrate on which is deposited the conducting layer.

In a continuous manufacturing process, when the composite substrate is in the form of a plate, it can advantageously pass within a heated laminator at the baking step S14.

More generally, the baking step S14 makes it possible to bake the conducting ink through the use of heating, optionally combined with application of pressure to the surface on which the conducting ink has been deposited.

Optionally, the baking step S14 may be implemented in two parts: first of all, pre-baking or drying of the ink may be implemented, at a temperature of the order of 50° C. The ink so deposited passes from the liquid state to the solid state, facilitating the manipulation or the transport of the composite substrate during the process for manufacturing the conducting electrical device.

A step of actual baking, at a higher temperature comprised between 100° C. and 150° C., may then be implemented in order to eliminate the solvents and the volatile compounds of the conducting ink and so obtain the properties of electrical conductivity of that ink.

Lastly, the manufacturing process can optionally comprise after the depositing step S12 or baking step S14 a step of final shaping S15 of the composite substrate.

This step of final shaping S15 may be similar to the step of initial shaping S11.

The final shaping step S15 may thus be implemented, as described above, by thermoforming or thermocompression.

This new temperature rise of the composite substrate in the final shaping step S15 makes it possible once again to heat the composite substrate on which has been deposited the conducting layer, and thereby optionally carry out a second baking of the conducting layer after the baking step S14.

The use of a thermo-formable ink, with the composite substrate itself being thermo-formable makes it possible to shape electrically functional surfaces in three dimensions. The hot shaping of the composite substrate implemented in the final shaping step S15 will act as a second baking of the conducting ink, which will further improve those properties of electrical conductivity.

The manufacturing process described above thus enables an electrically conducting device to be obtained from a composite substrate of lignocellulosic material.

The functionalization of the composite substrate is obtained thanks to the depositing of at least one conducting layer, in direct contact with the surface of the composite substrate, without requiring the use of an adhesive and a plastic film incorporating printed electronics.

The manufacturing process thus implemented is simple and of low cost, limiting the number of parts required and the steps of assembly for the production of an electrically conducting device.

The technique of depositing one or more layers of conducting ink at ambient temperature on a lignocellulosic material impregnated with a filling compound makes it possible to produce very diverse electrically conducting devices.

In particular, when the composite substrate is a plate comprising two opposite faces, the manufacturing process may comprise a step S12 of depositing one or more conducting layers on at least one surface of the opposite faces of the plate.

It is thus possible to produce different electrically conducting elements on one of the faces of the plate.

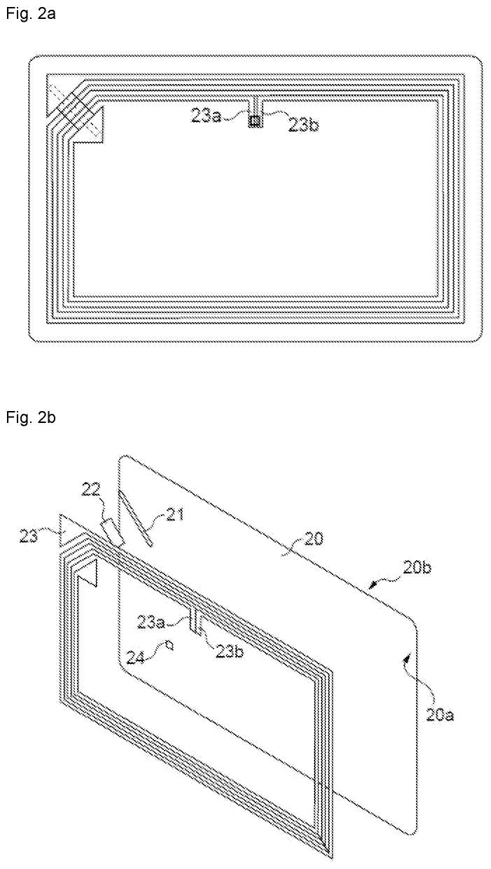

In relation with FIGS. 2a and 2b, a description will thus be given of an example of implementation of the manufacturing process, making it possible to produce an antenna on a composite substrate of plate form.

In this example embodiment, the composite substrate is a plate 20 comprising two opposite faces 20a and 20b. The manufacturing process comprises a step of depositing a conducting layer on the planar surface of a face 20a of the plate 20.

In this example embodiment, the manufacturing process comprises two successive depositing steps S12: a first depositing step S12 makes it possible to deposit a first conducting track 21, for example by screen-printing with a conducting ink.

An insulator 22, produced for example by screen-printing of an electrically insulating ink, is disposed on the first conducting track 21. The insulator 22 makes it possible to separate the different conducting layers produced on the same face 20a of the plate 20.

A second depositing step S12 is then implemented to produce a second conducting track 23.

The second conducting track 23 is produced in a spiraled shape so as to form an antenna. The second conducting track 23 is electrically connected to the first conducting track 21.

An electronic component 24 may also be mounted at the surface, such as an SMD (surface mounted device). The electronic component 24 may thus be soldered for example to two pads 23a, 23b of the second conducting track 23. The electronic component 24 may be a memory.

The electrically conducting device thus takes the form of an identity card type card, access control badge or payment card. The thickness of the plate 20 may be less than 10 mm, and for example be comprised between 0.1 and 3 mm, or between 1 and 3 mm.

The manufacturing process thus makes it possible to functionalize one of the two faces 20a of the plate 20.

The radio antenna so produced can operate in accordance with different types of well-known communication protocol of RFID, Bluetooth, Wi-Fi, or NFC (Near Field Communication) type.

Of course, the example embodiment of FIGS. 2a and 2b is not limiting.

One of the faces 20a of the plate 20 could also be functionalized by the deposition, by screen-printing for example, of a trace for electrodes forming for example a resistive or capacitive sensor.

As the composite substrate of impregnated lignocellulosic material is dielectric, the second face 20b of the plate 20 thus has a touch function, making it possible to act through the plate 20 on the sensor produced on the first face 20a of the plate 20.

It is thus possible to produce an interface for control of an electronic object. The composite substrate 20 can then preferably be translucent, the light transmission coefficient of the composite substrate 20 being equal to at least 3%.

It is thus possible, through the composite substrate 20, to view a light signal emitted by an electronic object controlled by the control interface.

More generally, the deposition of a conducting layer makes it possible to produce a conducting circuit or tracks on which may be soldered one or more components that are SMD or that pass through.

It is also possible to deposit a carbon-bearing conducting ink, conferring a resistive character upon the conducting ink.

When a current passes in a track produced with such a conducting ink, a heating element is obtained, which may be thermo-regulated.

It is thus possible to produce an electrically conducting device forming a resistor, or an energy-generating device or for instance merely an electrical conductor.

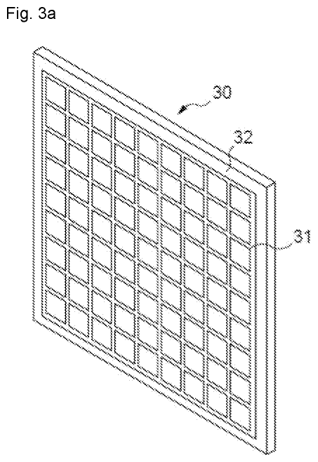

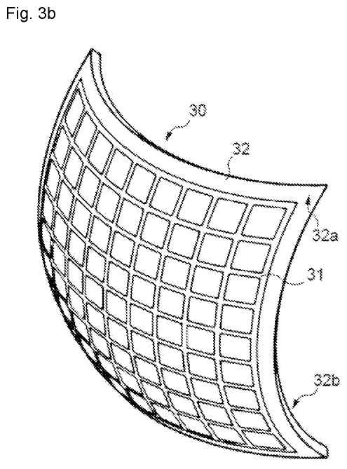

A description will now be given with reference to FIGS. 3a and 3b of another example of implementation of the manufacturing process making it possible

to produce a touch interface from lignocellulosic material 30.

As illustrated in FIG. 3a, using a conducting ink that is deposited for example by screen-printing, a network is produced of conducting tracks 31 in matrix form on a face 32a of a composite substrate 32 of lignocellulosic material impregnated with an impregnation polymer.

The touch sensor so produced may be resistive or capacitive in nature.

As illustrated in FIG. 3b, the composite substrate 32, after deposition of a conducting layer, may be shaped, for example by thermo-forming, to produce an electrically conducting device in three dimensions.

In the illustrated example, the electrically conducting device is thus shaped while hot to constitute a surface, having two radiuses of curvature, such as a portion of a sphere.

Of course, any type of warped surface with two radiuses of curvature could be shaped while hot.

As described above, it is thus possible to produce a touch interface 30, having two or three dimensions, by virtue of the dielectric composite substrate.

The lignocellulosic material is preferably at least partly delignified and the refractive index of the filling compound is comprised between 1.35 and 1.70

A refractive index is chosen for the filling compound that is close to that of cellulose, of the order of 1.47.

Thus, the light coming from an electronic object or a screen placed under the touch interface 30 is deviated little or not at all, improving the rendition of light for the user.

The delignification of the composite substrate 32 enables light to be passed without diffraction of the light ray.

Preferably, when the touch interface 30 is configured to be used to control an electronic object or a display screen, it is advantageous to use a transparent conducting ink in combination with the translucent or transparent composite substrate.

It is furthermore possible to obtain a touch interface by coupling several plates of lignocellulosic material such that the overall touch interface can have a thickness greater than 10 mm.

This type of touch interface is well suited to protect fragile or sensitive electronic objects, and may for example be used in applications where toughened glass is conventionally necessary.

It will be noted that in the example embodiments illustrated in FIGS. 2a, 2b, 3a and 3b, only one of the faces 20a, 32a of the composite substrate 20, 32 is functionalized using a conducting layer deposit. The other face 20b, 32b of the electrically conducting device thus forms a face for presentation, and in particular has a look and appearance of a lignocellulosic material, with the characteristics and veining of the wood used to manufacture the composite substrate.

It is thus possible to form parts for presentation in different fields, and for example in particular an automotive, nautical or aeronautical vehicle part, or for instance a member or accessory in the building, packaging or furnishings fields.

Moreover, it is possible to produce an object of lignocellulosic material upon which it is desired to confer a touch detection function directly integrated into the object.

For example, the casing of a mobile phone may be produced from an electrically conducting device as described above making it possible to functionalize the back face of the mobile phone, on the opposite side from screen on the front.

By way of example, the manufacturing process also makes it possible to produce a electrically conducting device that can be used as a strap for a smart watch or as a watch body.

An electrically conducting device of lignocellulosic material may also be used for sports equipment such as skis, or mass-market goods (e.g. glasses or telephone covers).

The electrically conducting device of lignocellulosic material may also be a furnishing item, for example an office table with an integrated touch screen, or a door with a touch detection device.

Such an electrically conducting device can also be used in a vehicle cabin (dashboard, door member) in the automotive, nautical or aeronautical field.

It will be noted that the electrically conducting device of lignocellulosic material more generally makes it possible to replace all the types of interface today produced from plastic or from glass but which have drawback of being fragile or thick and heavy and of having an ecological impact detrimental to the environment since petro-sourced.

Of course, the example embodiments described above are in no way limiting.

In particular, the composite substrate may have a very diverse shape in 2D or 3D, making it possible to produce objects of complex geometry, of the type having warped or hyperbolic paraboloid surfaces.

Furthermore, the deposition of a conducting layer may be carried out on several faces of the composite substrate.

1. A process for manufacturing an electrically conducting device from lignocellulosic material, wherein it comprises the following steps:
impregnating the lignocellulosic material with at least one filling compound so as to produce a composite substrate; and
depositing at least one conducting layer on at least one surface of the composite substrate so as to produce the electrically conducting device.

2. The manufacturing process according to claim 1, wherein the composite substrate comprises a fraction of a filling compound comprised between 30% and 80% by weight relative to the total weight of the substrate.

3. The manufacturing process according to claim 2, wherein the filling compound is an impregnation polymer, for example a thermoplastic polymer of acrylic type.

4. The manufacturing process of claim 1, wherein the lignocellulosic material is wood comprising lignin and a network of cellulose and hemicellulose, the wood being at least partially delignified.

5. The manufacturing process of claim 1, wherein the composite substrate comprises at least one planar face, a conducting track being deposited on the surface of the at least one planar face.

6. The manufacturing process according to claim 5, wherein it further comprises a step of baking the conducting track, optionally followed by a step of shaping the composite substrate so as to produce an electrically conducting device in three dimensions.

7. The manufacturing process of claim 1, wherein the filling compound is a resin having a filler of metal particles, the manufacturing process further comprising a step of activating the metal particles by ultraviolet or laser beam before the depositing step.

8. The manufacturing process of claim 1, wherein it further comprises a step of shaping the composite substrate after the impregnating step and before the depositing step.

9. The manufacturing process of claim 1, wherein the composite substrate is a plate comprising two opposite faces, the manufacturing process comprising a step of depositing at least one conducting layer on at least one surface of one of the two faces of the plate.

10. The manufacturing process of claim 9, wherein the thickness of the plate is less than 10 mm.

11. The manufacturing process of claim 1, wherein the composite substrate is translucent or transparent, the light transmission coefficient of the translucent substrate being at least equal to 3%.

12. The manufacturing process of claim 1, wherein the refractive index of the filling compound is comprised between 1.35 and 1.70.

13. The manufacturing process of claim 1, wherein the at least one conducting layer comprises a transparent conducting ink.

14. An electrically conducting device of lignocellulosic material, manufactured according to the method of claim 1.

15. The electrically conducting device of claim 14, wherein the device comprises an interface for control of an electronic object, a payment card, an access control badge, a sensor, a transistor, a resistor, an energy generating device, or an electrical conductor.

16. The electrically conducting device of claim 15, wherein it forms an automotive, nautical or aeronautical vehicle part.
